(19) United States
(12) Patent Application Publication
(10) Pub. No.: US 2019/0245079 A1
(43) Pub. Date: Aug. 8, 2019

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventors: Fumikazu Imai, Tsukuba (JP); Takahito Kojima, Matsumoto (JP)

(73) Assignee: FUJI ELECTRIC CO., LTD., Kawasaki-shi (JP)

(21) Appl. No.: 16/234,939

(22) Filed: Dec. 28, 2018

(30) Foreign Application Priority Data
Feb. 6, 2018 (JP) 2018-019693

(51) Int. Cl. H01L 29/78; H01L 29/66; H01L 29/16; H01L 29/36

(52) U.S. Cl. CPC H01L 29/7813; H01L 29/36; H01L 29/1608; H01L 29/66734

(57) ABSTRACT

A vertical MOSFET having a trench gate structure includes an n⁻-type drift layer and a p-type base layer formed by epitaxial growth. In the p-type base layer, an n⁺-type source region is provided. A trench that penetrates the p-type base layer and the n⁺-type source region, and reaches the n⁻-type drift layer is provided. The first p⁺-type region is in contact with a bottom of the trench and is implanted with an impurity that determines a conductivity type of the first p⁺-type region and a first element that bonds with a second element that is displaced by the impurity, the impurity and the second element being implanted at a predetermined ratio.

### CROSS REFERENCE TO RELATED APPLICATIONS

This application is based upon and claims the benefit of priority of the prior Japanese Patent Application No. 2018-019693, filed on Feb. 6, 2018, the entire contents of which are incorporated herein by reference.

### BACKGROUND

### 1. Field

Embodiments of the invention relate to a semiconductor device and a method of manufacturing a semiconductor device.

### 2. Description of Related Art

Conventionally, in a power semiconductor element, to facilitate reduction of ON resistance of the element, a vertical metal oxide semiconductor field effect transistor (MOSFET) having a trench structure is fabricated (manufactured). In the vertical MOSFET, compared to a planar structure in which the channel is formed parallel to the substrate surface, cell density per unit area may be increased by a trench structure in which a channel is formed orthogonal to a substrate surface, enabling current density per unit area to be increased, which is advantageous from an aspect of cost.

Nonetheless, when a trench structure is formed in a vertical MOSFET, the structure is such that an inner wall of the trench is covered entirely by a gate insulating film to form the channel in a vertical direction and a portion of the gate insulating film at a bottom of the trench is near a drain electrode, whereby high electric field tends to be applied to the portion of the gate insulating film at the bottom of the trench. In particular, an ultra-high voltage element is fabricated with a wide bandgap semiconductor material (semiconductor material having a bandgap that is wider than that of silicon, e.g., silicon carbide (SiC)), and therefore, adverse effects on the gate insulating film at the bottom of the trench significantly reduce reliability.

According to a technique proposed as a method to solve such problems, in a vertical MOSFET with a trench structure having a striped planar pattern, a p⁺-type base region is provided between trenches, in a striped shape parallel to the trenches (for example, refer to Japanese Laid-Open Patent Publication No. 2009-260253). According to another proposed technique, a p⁺-type base region is provided at the bottom of the trench, in a striped shape parallel to the trench.

FIG. 9 is a cross-sectional view of a structure of a conventional silicon carbide semiconductor device. The conventional silicon carbide semiconductor device depicted in FIG. 9 includes at a front surface (surface on a p-type base layer 106 side) side of a semiconductor base (hereinafter, silicon carbide base) 1000 containing silicon carbide, a MOS gate having a typical gate structure. The silicon carbide base (semiconductor chip) 1000 is formed by sequentially forming by epitaxial growth on an n⁺-type supporting substrate (hereinafter, n⁺-type silicon carbide substrate) 101 containing silicon carbide, silicon carbide layers constituting an n⁻-type drift layer 102, an n-type region 105 that is a current diffusion region, and the p-type base layer 106.

In the n-type region 105, a first p⁺-type region 103 is selectively provided so as to cover entirely a bottom of a trench 1018. The first p⁺-type region 103 is provided at a depth not reaching the n⁻-type drift layer 102. Further, in the n-type region 105, between (mesa part) the trench 1018 and an adjacent trench 1018, a second p⁺-type region 104 is selectively provided. The second p⁺-type region 104 is in contact with the p-type base layer 106 and is provided at a depth not reaching the n⁻-type drift layer 102. Reference numerals 107, 108, 109, 1010, 1011, and 1012 are an n⁺-type source region, a p⁺-type contact region, a gate insulating film, a gate electrode, an interlayer insulating film, and a source electrode, respectively.

In the vertical MOSFET having the structure depicted in FIG. 9, pn junctions of the first p⁺-type region 103 and the second p⁺-type region 104 with the n-type region 105 are at positions deeper than the trench 1018. Therefore, electric field concentrates at boundaries of the first p⁺-type region 103 and the second p⁺-type region 104 with the n-type region 105, enabling a concentration of electric field at the bottom of the trench 1018 to be mitigated.

Further, a technique has been proposed in which a part of a semiconductor layer of an upper corner part of the trench is moved onto the bottom of the trench by an annealing process, whereby a trench bottom impurity region of a second conductivity type is formed covering the bottom of the trench and having a high-quality crystal quality with few crystal defects (for example, refer to International Publication No. WO 2013/118437).

### SUMMARY

According to an embodiment of the present invention, a semiconductor device includes a semiconductor substrate of a first conductivity type; a first semiconductor layer of the first conductivity type, provided on a front surface of the semiconductor substrate; a second semiconductor layer of a second conductivity type, provided on a first side of the first semiconductor layer, opposite a second side of the first semiconductor layer toward the semiconductor substrate; a first semiconductor region of the first conductivity type, selectively provided in the second semiconductor layer, the first semiconductor region having an impurity concentration that is higher than that of the semiconductor substrate; a trench penetrating the first semiconductor region and the second semiconductor layer, and reaching the first semiconductor layer; a gate electrode provided in the trench, via a gate insulating film; a first electrode in contact with the first semiconductor region and the second semiconductor layer; a second electrode provided on a rear surface of the semiconductor substrate; and a second semiconductor region of the second conductivity type, selectively provided in the first semiconductor layer, the second semiconductor region contacting a bottom of the trench and having an impurity concentration that is higher than that of the second semiconductor layer. The second semiconductor region is implanted with an impurity and a first element at a predetermined ratio, the impurity determining a conductivity type of the second semiconductor region and displacing a second element, the first element bonding with the displaced second element.

In the embodiment, the semiconductor device further includes a third semiconductor region of the second conductivity type, selectively provided in the first semiconductor layer, the third semiconductor region having an impurity concentration higher than that of the second semiconductor layer. An interface of the third semiconductor region and the first semiconductor layer is closer to the semiconductor substrate than is an interface of the second semiconductor region and the first semiconductor layer.

In the embodiment, the first element is carbon, when the impurity is an impurity that enters a silicon site. The first element is silicon, when the impurity is an impurity that enters a carbon site.

In the embodiment, the impurity is aluminum and the first element is carbon.

According to another embodiment of the present invention, a method of manufacturing a semiconductor device, includes forming a first semiconductor layer of a first conductivity type on a front surface of a semiconductor substrate of the first conductivity type; forming a second semiconductor layer of a second conductivity type on a first side of the first semiconductor layer, opposite a second side of the first semiconductor layer toward the semiconductor substrate; selectively forming a first semiconductor region of the first conductivity type in the second semiconductor layer, the first semiconductor region having an impurity concentration that is higher than that of the semiconductor substrate; forming a trench that penetrates the first semiconductor region and the second semiconductor layer, and reaches the first semiconductor layer; forming an oxide film in the trench; removing the oxide film at a bottom of the trench; forming a second semiconductor region of the second conductivity type in the first semiconductor layer by co-implanting in the bottom of the trench, an impurity that determines a conductivity type and a first element that bonds with a second element that is displaced by the impurity, the second semiconductor region being in contact with the bottom of the trench and having an impurity concentration that is higher than that of the second semiconductor layer; forming a gate electrode in the trench, via a gate insulating film; forming a first electrode in contact with the first semiconductor region and the second semiconductor layer; and forming a second electrode on a rear surface of the semiconductor substrate.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of the silicon carbide semiconductor device according to the embodiment;

FIG. 2 is a cross-sectional view of the silicon carbide semiconductor device according to the embodiment during manufacture;

FIG. 3 is a cross-sectional view of the silicon carbide semiconductor device according to the embodiment during manufacture;

FIG. 4 is a cross-sectional view of the silicon carbide semiconductor device according to the embodiment during manufacture;

FIG. 5 is a cross-sectional view of the silicon carbide semiconductor device according to the embodiment during manufacture;

FIG. 6 is a cross-sectional view of the silicon carbide semiconductor device according to the embodiment during manufacture;

FIG. 7 is a cross-sectional view of the silicon carbide semiconductor device according to the embodiment during manufacture;

FIG. 8 is a cross-sectional view of the silicon carbide semiconductor device according to the embodiment during manufacture;

FIG. 9 is a cross-sectional view of a structure of a conventional silicon carbide semiconductor device;

FIG. 10 is a graph depicting leak current with respect to drain voltage in regions of the conventional silicon carbide semiconductor device; and

FIG. 11 is a graph depicting high voltage leak of the conventional silicon carbide semiconductor device.

### DESCRIPTION OF EMBODIMENTS

First, problems associated with the related techniques will be discussed. In the described conventional structures, to form the first p⁺-type region 103 so as to be positioned at the bottom of the trench 1018, with consideration of process margin, the first p⁺-type region 103 has to be formed to be widened. Therefore, to further reduce cell pitch, photolithography of higher precision is necessary, manufacturing difficulty increases, and there is a limit to the extent that the element may be reduced in size. On the other hand, when the first p⁺-type region 103 is not provided, the concentration of electric field at the bottom of the trench 1018 cannot be mitigated, whereby the targeted breakdown voltage cannot be realized.

There is a method that enables reductions in size. According to the method, the trench 1018 is formed without forming the first p⁺-type region 103 prior to forming the trench 1018. Thereafter, the mask used in the etching is used to perform self-aligning ion implantation and form the first p⁺-type region 103 at the bottom of the trench 1018. Here, to suppress ion implantation into the side walls of the trench 1018, an oxide film is formed in the trench 1018, for example, by chemical vapor deposition (CVD), whereby the surface is protected and after the oxide film at the bottom of the trench 1018 is removed by etching, the self-aligning ion implantation is performed.

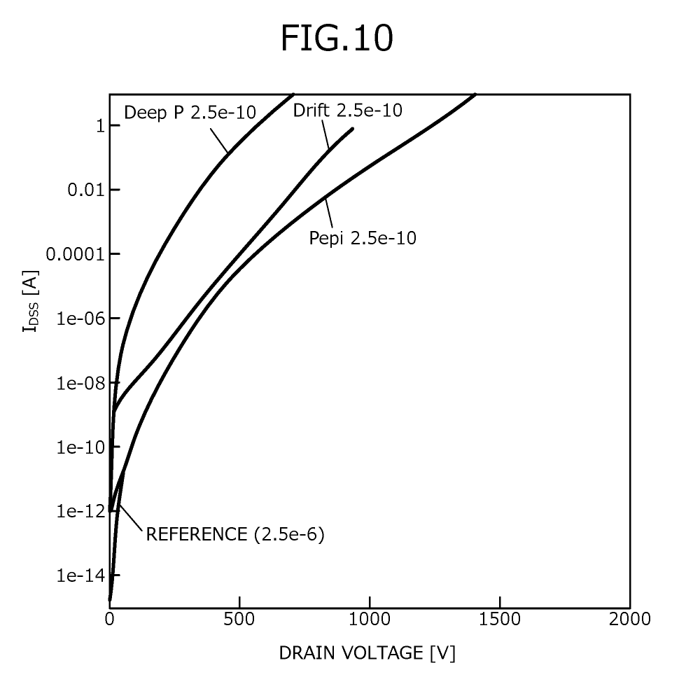

Nonetheless, with this method, crystal defects occur in the first p⁺-type region 103 due to the ion implantation. FIG. 10 is a graph depicting leak current with respect to drain voltage in regions of the conventional silicon carbide semiconductor device. FIG. 10 depicts results of simulation of leak current l_{DSS} between a drain and source, in cases when in the n⁻-type drift layer 102, the second p⁺-type region 104 and the p-type base layer 106, defect amounts are 2.5×10⁻⁶/cm³ and 2.5×10⁻¹⁶/cm³ in each.

In FIG. 10, a horizontal axis indicates drain voltage in units of V and a vertical axis indicates the leak current l_{DSS} in units of μA. Further, a reference curve indicates simulation results when the defect amount of the n⁻-type drift layer 102, the second p⁺-type region 104 and the p-type base layer 106 is 2.5×10⁻⁶/cm³; a Pepi curve indicates simulation results when the defect amount of the p-type base layer 106 is 2.5×10⁻¹⁶/cm³; a Drift curve indicates simulation results when the defect amount of the n⁻-type drift layer 102 is 2.5×10⁻¹⁶/cm³; and a Deep P curve indicates simulation results when the defect amount of the second p⁺-type region 104 is 2.5×10⁻¹⁰/cm³. From these results, it is found that when the defect amount of the second p⁺-type region 104 is large, the leak current l_{DSS} increases. Further, when crystal defects occur in the first p⁺-type region 103, similarly to the case of the second p⁺-type region 104, the leak current l_{DSS} increases when the voltage is high.

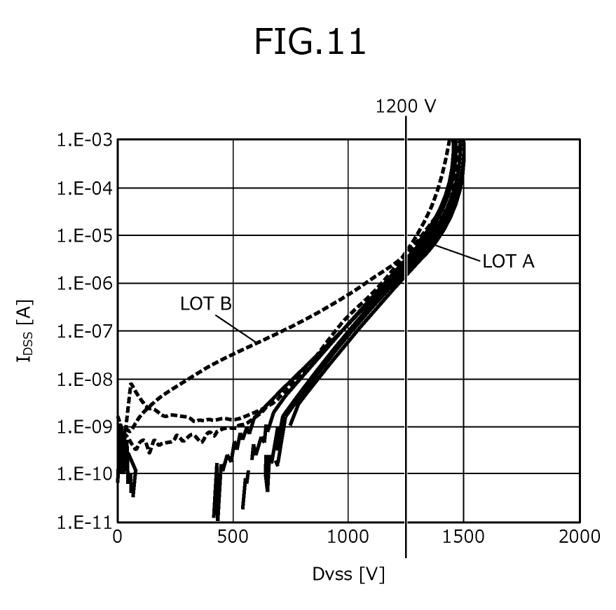

FIG. 11 is a graph depicting high voltage leak of the conventional silicon carbide semiconductor device. In FIG. 11, a vertical axis indicates drain saturation current in units of A and a horizontal axis indicates voltage between the drain and source in units of V. As depicted in FIG. 11, in the conventional semiconductor device, at a high voltage, the leak current l_{DSS} is about 1 μA.

Embodiments of a semiconductor device and a method of manufacturing a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without +or −. In the description of the embodiments below and the accompanying drawings, main portions that are identical will be given the same reference numerals and will not be repeatedly described.

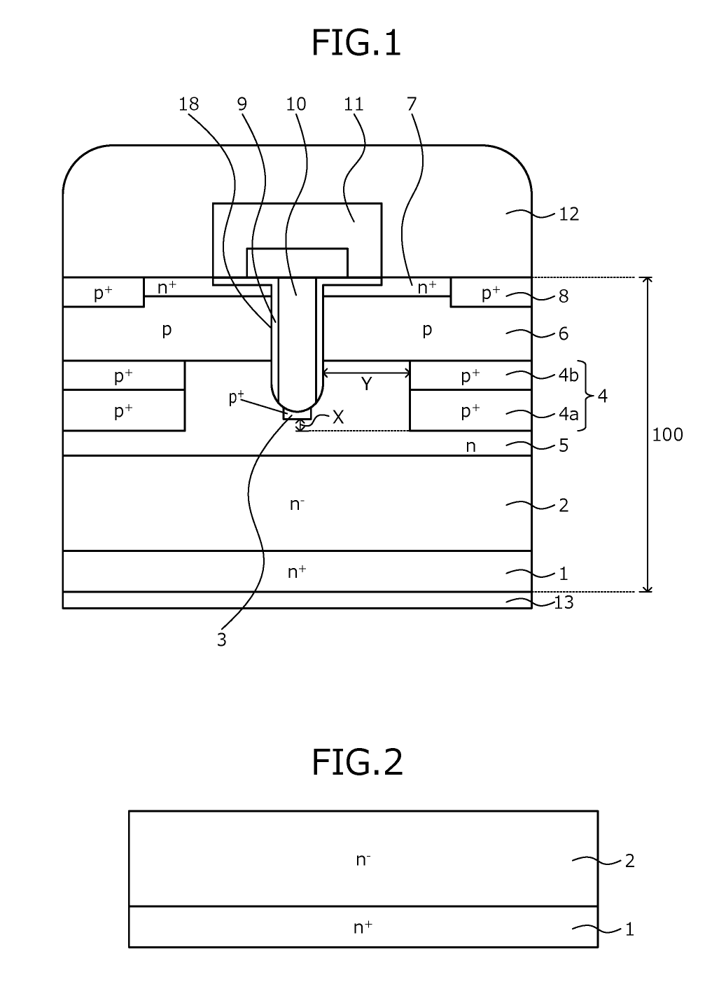

A semiconductor device according to an embodiment of the present invention is configured using a semiconductor material (hereinafter, wide-bandgap semiconductor material) having a bandgap wider than that of silicon. Here, a structure of a semiconductor device (silicon carbide semiconductor device) using, for example, silicon carbide (SiC), as the wide-bandgap semiconductor material will be described as an example. FIG. 1 is a cross-sectional view of a structure of the silicon carbide semiconductor device according to the embodiment. The silicon carbide semiconductor device according to the embodiment depicted in FIG. 1 is a MOSFET that has a MOS gate at a front surface (surface on a p-type base layer 6 side) side of a semiconductor base (silicon carbide base: semiconductor chip) 100 containing silicon carbide.

The silicon carbide base 100 is formed by sequentially forming on an n⁺-type supporting substrate (n⁺-type silicon carbide substrate: semiconductor substrate of a first conductivity type) 1 containing silicon carbide, silicon carbide layers constituting an n⁻-type drift layer (first semiconductor layer of the first conductivity type) 2 and the p-type base layer (second semiconductor layer of a second conductivity type) 6. The MOS gate is constituted by the p-type base layer 6, an n⁺-type source region (first semiconductor region of the first conductivity type) 7, a p⁺-type contact region 8, a trench 18, a gate insulating film 9, and a gate electrode 10. In particular, in a surface layer on a source side (side facing toward a source electrode 12) of the n⁻-type drift layer 2, an n-type region 5 is provided so as to be in contact with the p-type base layer 6. The n-type region 5 is a so-called current spreading layer (CSL) that reduces carrier spreading resistance. The n-type region 5, for example, is provided uniformly along a direction (hereinafter, horizontal direction) parallel to a base front surface (front surface of the silicon carbide base 100).

In the n-type region 5, a first p⁺-type region (second semiconductor region of the second conductivity type) 3 and a second p⁺-type region (third semiconductor region of the second conductivity type) 4 are each selectively provided. The second p⁺-type region 4 is constituted by a lower second p⁺-type region 4a and an upper second p⁺-type region 4b. The first p⁺-type region 3 is provided in contact with a bottom of the trench 18. The first p⁺-type region 3 is provided from a position further on a drain side than is an interface of the p-type base layer 6 and the n-type region 5, to a depth not reaching an interface of the n-type region 5 and the n⁻-type drift layer 2. Provision of the first p⁺-type region 3 enables formation of a pn junction between the first p⁺-type region 3 and the n-type region 5, near the bottom of the trench 18. The first p⁺-type region 3 has an impurity concentration that is higher than that of the p-type base layer 6.

Further, in FIG. 1, while a width of the first p⁺-type region 3 is narrower than a width of the trench 18, configuration is not limited hereto. For example, the width of the first p⁺-type region 3 may be equal to or greater than the width of the trench 18.

The first p⁺-type region 3 is formed by ion implantation of a p-type impurity, e.g., aluminum (Al). Aluminum is an element that enters a silicon site by ion implantation and therefore, aluminum is disposed in silicon carbide crystal, near silicon. Thus, silicon (Si) is displaced by aluminum and the displaced silicon becomes a defect.

Therefore, in the embodiment, to reduce defects, an element, e.g., carbon (C), that corresponds to the p-type impurity is implanted in the first p⁺-type region 3 at a predetermined ratio. As a result, the implanted carbon and the displaced silicon bond with each other, crystallize with the silicon carbide, and prevent the silicon from becoming a defect. Here, a predetermined ratio is an amount necessary for bonding with the silicon displaced by the implantation of aluminum. In particular, a doping amount (D_{C}) of carbon is an amount satisfying 0.7≤D_{C}/D_{AI}≤1.3 with respect to a doping amount (D_{AI}) of aluminum. The implanted carbon and the displaced silicon bond with each other, whereby a carbon amount of the first p⁺-type region 3 is greater than a carbon amount of the n-type region 5 at a side wall of the trench 18.

Further, the first p⁺-type region 3 may be formed by ion implantation of a p-type impurity other than aluminum, for example, boron (B). In this case, an element that corresponds to the p-type impurity is implanted in the first p⁺-type region 3 at a predetermined ratio. For example, when the p-type impurity is an element that enters a silicon site, the element that corresponds to the p-type impurity is carbon and similarly to aluminum, carbon is implanted in the first p⁺-type region 3 at a predetermined ratio. On the other hand, when the p-type impurity is an element that enters a carbon site, the element that corresponds to the p-type impurity is silicon and contrary to aluminum, silicon is implanted in the first p⁺-type region 3 at a predetermined ratio. As a result, the carbon displaced by the p-type impurity bonds with the implanted silicon and crystallizes with the silicon carbide, whereby the carbon is prevented from becoming a defect.

The lower second p⁺-type region 4a is selectively provided separated from the n⁻-type drift layer 2 and in contact with the upper second p⁺-type region 4b. An interface of the lower second p⁺-type region 4a and the upper second p⁺-type region 4b is provided closer to the source electrode 12 than is the bottom of the trench 18. The upper second p⁺-type region 4b is provided so as to be in contact with the p-type base layer 6 and the lower second p⁺-type region 4a.

Further, a bottom of the lower second p⁺-type region 4a is at a position deeper toward the n⁺-type silicon carbide substrate 1 than is a bottom of the first p⁺-type region 3. In other words, the interface of the lower second p⁺-type region 4a and the n-type region 5 is closer to the n⁺-type silicon carbide substrate 1 than is an interface of the first p⁺-type region 3 and the n-type region 5. The bottom of the lower second p⁺-type region 4a may be at a depth equal to that of the bottom of the first p⁺-type region 3.

However, as depicted in FIG. 1, when the width of the first p⁺-type region 3 is narrower than the width of the trench 18, to realize a targeted breakdown voltage at the lower second p⁺-type region 4a, the bottom of the lower second p⁺-type region 4a may be at a position deeper than that of the first p⁺-type region 3. Further, the lower second p⁺-type region 4a and the first p⁺-type region 3 are formed by respectively different processes and therefore, formation at the same depth is difficult. Thus, the bottom of the lower second p⁺-type region 4a may be positioned deeper than the bottom of the first p⁺-type region 3. For example, a length of the trench 18 may be reduced, whereby the bottom of the first p⁺-type region 3 becomes shallower.

For example, a difference X in the depths of the lower second p⁺-type region 4a and the first p⁺-type region 3 may be in a range from 0.1 to 1.0 μm. Further, a distance Y from the trench 18 to the upper second p⁺-type region 4b and the lower second p⁺-type region 4a may be in a range from 0.2 to 2.0 μm.

In the p-type base layer 6, the n⁺-type source region 7 and the p⁺-type contact region 8 are each selectively provided so as to be in contact with each other. A depth of the p⁺-type contact region 8, for example, may be equal to a depth of the n⁺-type source region 7, or may be deeper than the depth of the n⁺-type source region 7.

The trench 18 penetrates the n⁺-type source region 7 and the p-type base layer 6 from the base front surface, and reaches the n-type region 5 and the first p⁺-type region 3. In the trench 18, the gate insulating film 9 is provided along side walls of the trench 18 and on the gate insulating film 9, the gate electrode 10 is provided. A source-side end part of the gate electrode 10 may or may not protrude outward from the base front surface. The gate electrode 10, at a non-depicted part, is electrically connected with a gate pad. An interlayer insulating film 11 is provided on the base front surface overall so as to cover the gate electrode 10 embedded in the trench 18.

The source electrode (first electrode) 12 is in contact with the n⁺-type source region 7 and the p⁺-type contact region 8 through a contact hole opened in the interlayer insulating film 11, and is electrically insulated from the gate electrode 10 by the interlayer insulating film 11. Between the source electrode 12 and the interlayer insulating film 11, for example, a barrier metal that prevents diffusion of metal atoms from the source electrode 12 toward the gate electrode 10 may be provided. On the source electrode 12, a source electrode pad (not depicted) is provided. On a rear surface (rear surface of the n⁺-type silicon carbide substrate 1 that constitutes an n⁺-type drain region) of the silicon carbide base 100, a drain electrode (second electrode) 13 is provided.

Further, in the embodiment, while an instance of the n⁺-type silicon carbide substrate 1 is depicted, even in a case of a p⁺-type silicon carbide substrate, defects may be similarly prevented. In this case, the first p⁺-type region 3 constitutes an n-type first n⁺-type region. For example, when an impurity of the first n⁺-type region is nitrogen, since nitrogen is an element that enters a carbon site, silicon is implanted at a predetermined ratio. Further, when the impurity of the first n⁺-type region is phosphorus (P), since phosphorus is an element that enters a silicon site, carbon is implanted at a predetermined ratio.

A method of manufacturing a silicon carbide semiconductor device according to the embodiment will be described. FIGS. 2, 3, 4, 5, 6, 7 and 8 are cross-sectional views of the silicon carbide semiconductor device according to the embodiment during manufacture. First, the n⁺-type silicon carbide substrate 1 that constitutes the n⁺-type drain region is prepared. Next, on a front surface of the n⁺-type silicon carbide substrate 1, the n⁻-type drift layer 2 is formed by epitaxial growth. For example, conditions of the epitaxial growth for forming the n⁻-type drift layer 2 may be set so that an impurity concentration of the n⁻-type drift layer 2 becomes about 1×10¹⁶/cm³. The state up to here is depicted in FIG. 2.

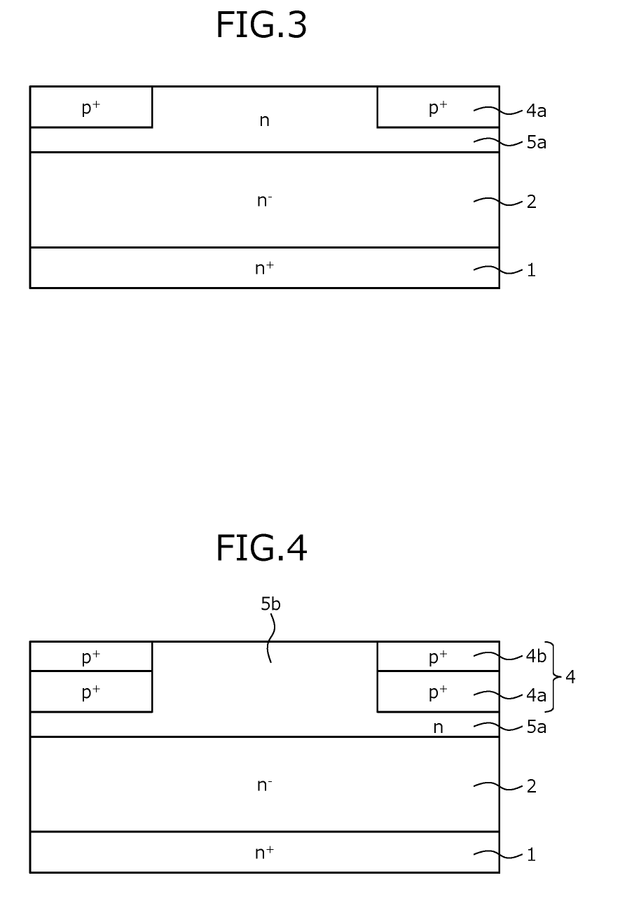

Next, on the n⁻-type drift layer 2, a lower n-type region 5a is formed by epitaxial growth. For example, conditions of the epitaxial growth for forming the lower n-type region 5a may be set so that an impurity concentration of the lower n-type region 5a becomes about 1×10¹⁷/cm³. The lower n-type region 5a is a part of the n-type region 5. Next, by photolithography and ion implantation of a p-type impurity, in a surface layer of the lower n-type region 5a, the lower second p⁺-type region 4a is selectively formed. For example, a dosing amount of the ion implantation for forming the lower second p⁺-type region 4a may be set so an impurity concentration thereof becomes about 5×10¹⁸/cm³. The state up to here is depicted in FIG. 3.

Next, on the lower n-type region 5a and the lower second p⁺-type region 4a, an upper n-type region 5b is formed by epitaxial growth. For example, conditions of the epitaxial growth for forming the upper n-type region 5b may be set so that an impurity concentration thereof becomes about equal to the impurity concentration of the lower n-type region 5a. The upper n-type region 5b is a part of the n-type region 5, and the lower n-type region 5a and the upper n-type region 5b collectively constitute the n-type region 5. Next, by photolithography and ion implantation of a p-type impurity, the upper second p⁺-type region 4b is selectively formed in a surface layer of the upper n-type region 5b. For example, a dosing amount of the ion implantation for forming the upper second p⁺-type region 4b may be set so that an impurity concentration thereof becomes about equal to the impurity concentration of the lower second p⁺-type region 4a. The state up to here is depicted in FIG. 4.

Next, on the upper n-type region 5b and the upper second p⁺-type region 4b, the p-type base layer 6 is formed by epitaxial growth. For example, conditions of the epitaxial growth for forming the p-type base layer 6 may be set so that an impurity concentration of the p-type base layer 6 becomes about 4×10¹⁷/cm³.

Next, by photolithography and ion implantation of an n-type impurity, in a surface layer of the p-type base layer 6, the n⁺-type source region 7 is selectively formed. For example, a dosing amount of the ion implantation for forming the n⁺-type source region 7 may be set so that an impurity concentration thereof becomes about 3×10²⁰/cm³.

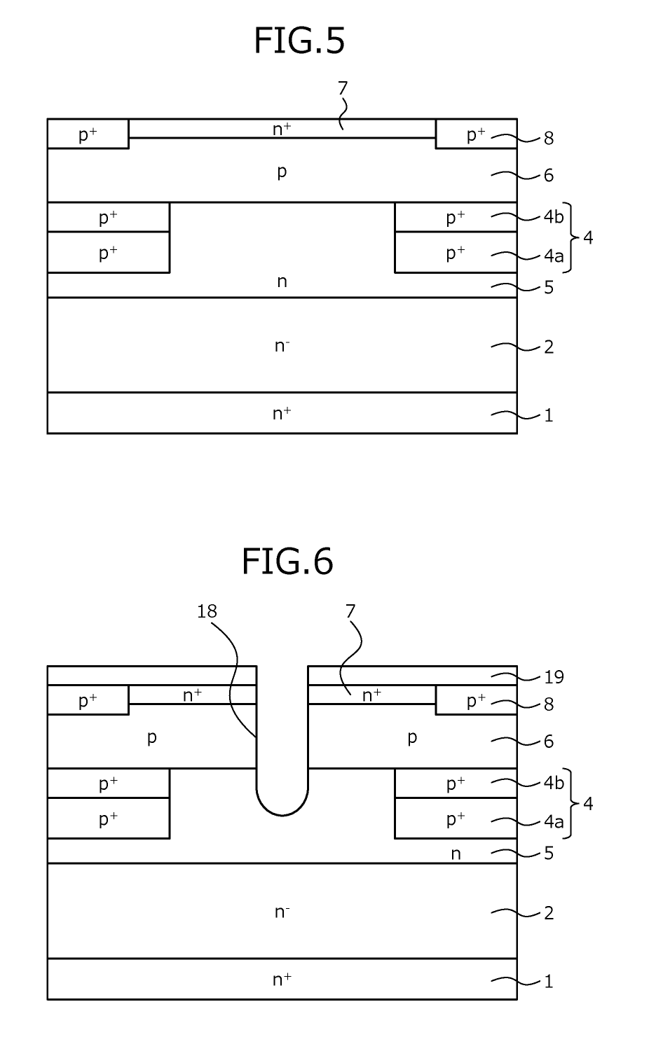

Next, by photolithography and ion implantation of a p-type impurity, in the surface layer of the p-type base layer 6, the p⁺-type contact region 8 is selectively formed so as to be in contact with the n⁺-type source region 7. For example, a dosing amount of the ion implantation for forming the p⁺-type contact region 8 may be set so that an impurity concentration thereof becomes about 3×10²⁰/cm³. A sequence in which the n⁺-type source region 7 and the p⁺-type contact region 8 are formed may be interchanged. The state up to here is depicted in FIG. 5.

Next, by photolithography and etching, the trench 18 is formed penetrating the n⁺-type source region 7 and the p-type base layer 6, and reaching the n-type region 5, at a depth of the lower second p⁺-type region 4a. Further, after trench etching, isotropic etching for removing damage of the trench 18 or hydrogen annealing for rounding corners of an opening part of the trench 18 and the bottom of the trench 18 may be performed. Any one of the isotropic etching and the hydrogen annealing alone may be performed. Further, after the isotropic etching is performed, the hydrogen annealing may be performed. The state up to here is depicted in FIG. 6. In FIG. 6, an oxide film 19, for example, contains silicon dioxide (SiO₂) and is a mask used in the etching for forming the trenches.

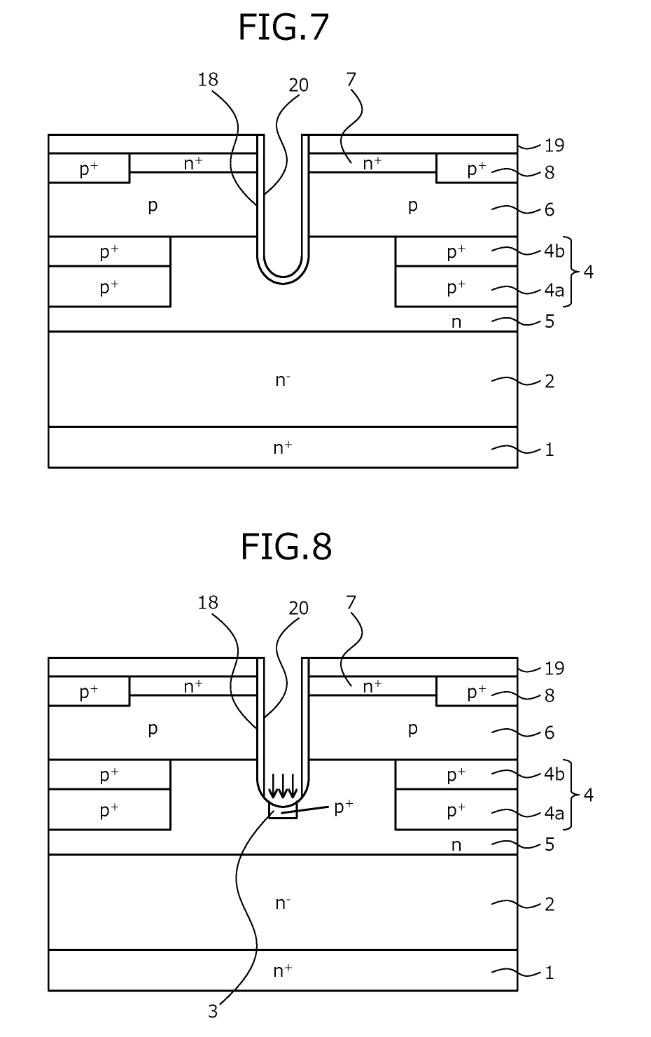

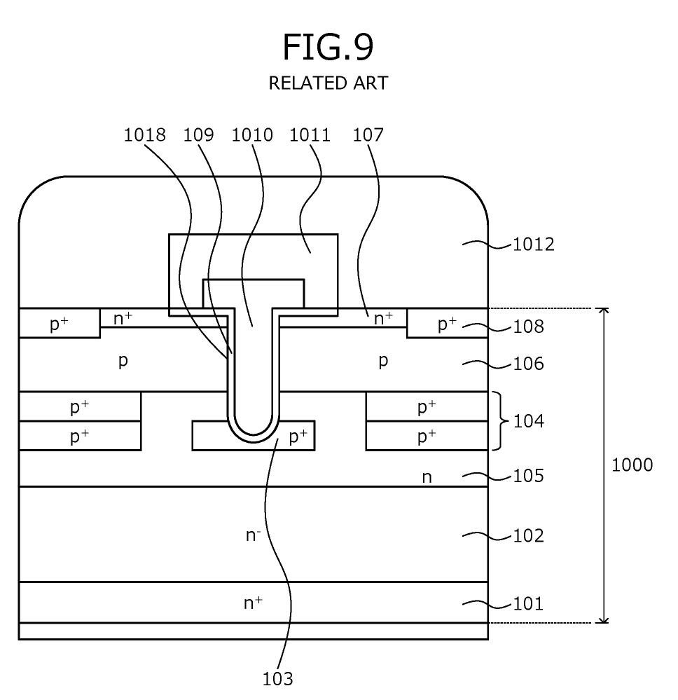

Next, to suppress ion implantation into side walls of the trench 18, for example, an oxide film 20 containing silicon dioxide is formed in the trench 18 by CVD. The oxide film 20 may be formed by thermal oxidation. The state up to here is depicted in FIG. 7.

Next, after the oxide film at the bottom of the trench 18 is removed by etching, self-aligning ion implantation is performed. Here, when the p-type impurity, for example, is aluminum atoms, an element that corresponds to the p-type impurity, e.g., carbon which corresponds to aluminum atoms, is co-implanted. As a result, the first p⁺-type region 3 is selectively formed at the bottom of the trench 18. Here, the first p⁺-type region 3 is formed so as to not be deeper than the lower second p⁺-type region 4a. In this manner, the first p⁺-type region 3 may be formed by self-alignment, i.e., by using the mask used in formation of the trench 18. Thus, since the first p⁺-type region 3 is formed by the same mask, shifting (misalignment) of the formation positions of the first p⁺-type region 3 and the trench 18 is eliminated. The state up to here is depicted in FIG. 8.

Next, to peel the oxide films 19, 20 and reduce surface roughness of the semiconductor base 100, a carbon coating layer that is a so-called carbon cap is formed on the surface of the semiconductor base 100 and activation annealing is performed.

Next, along the front surface of the silicon carbide base 100 and inner wall of the trench 18, the gate insulating film 9 is formed. Next, for example, poly-silicon is deposited so as to be embedded in the trench 18 and is etched, leaving the poly-silicon in the trench 18 to form the gate electrode 10. Here, etch back and etching may be performed so that the poly-silicon remains below a base surface part or patterning and etching may be performed, whereby the poly-silicon protrudes outward beyond the base surface part.

Next, the interlayer insulating film 11 is formed on the front surface of the silicon carbide base 100 overall so as to cover the gate electrode 10. The interlayer insulating film 11, for example, is formed by a non-doped silicate glass (NSG), a phosphosilicate glass (PSG), a borophosphosilicate glass (BPSG), a high temperature oxide (HTO), or a combination thereof. Next, the interlayer insulating film 11 and the gate insulating film 9 are patterned, forming a contact hole and exposing the n⁺-type source region 7 and the p⁺-type contact region 8.

Next, the barrier metal is formed so as to cover the interlayer insulating film 11 and is patterned to again expose the n⁺-type source region 7 and the p⁺-type contact region 8. Next, the source electrode 12 is formed so as to be in contact with the n⁺-type source region 7. The source electrode 12 may be formed so as to cover the barrier metal, or may be left in only the contact hole.

Next, the source electrode pad is formed so as to be embedded in the contact hole. A part of a metal layer deposited to form the source electrode pad may be used as the gate pad. On the rear surface of the n⁺-type silicon carbide substrate 1, at a contact part of the drain electrode 13, a metal film such as a nickel (Ni) film, a titanium (Ti) film, etc. is formed using sputter deposition. The metal film may be a stacked combination of a Ni film and Ti film. Subsequently, annealing such as rapid thermal annealing (RTA) is performed so that the metal film is converted into a silicide, forming an ohmic contact. Thereafter, for example, a thick film such as a stacked film including a Ti film, an Ni film, and a gold (Au) sequentially stacked is formed by electron beam (EB) deposition, etc., whereby the drain electrode 13 is formed. In this manner, MOSFET depicted in FIG. 1 is completed.

In the silicon carbide semiconductor device according to the embodiment, during high voltage, e.g., 1200V, the leak current l_{DSS} is 1×10⁻¹⁸ A or less. Compared to the leak current l_{DSS} of 1 μA for a conventional case of 1200V depicted in FIG. 11, in the silicon carbide semiconductor device according to the embodiment, the leak current l_{DSS} during high voltage may be suppressed.

As described above, according to the embodiment, when the first p⁺-type region of the bottom of the trench is formed, after etch back and removal of the oxide film, an element that corresponds to the p-type impurity is implanted at a predetermined ratio. As a result, an element that is displaced by the p-type impurity bonds with the element that corresponds to the p-type impurity and may be crystallized with silicon carbide. As a result, formation of defects by the element that is displaced by the p-type impurity may be reduced. Therefore, the silicon carbide semiconductor device according to the embodiment may suppress the leak current l_{DSS} during high voltage.

Further, in the embodiment, the first p⁺-type region is formed after trench formation and therefore, widening of the width of the first p⁺-type region for alignment is unnecessary. Thus, the silicon carbide semiconductor device according to the embodiment enables the width of the first p⁺-type region to be reduced, thereby enabling an interval between trenches to be reduced and size reductions to be achieved.

In the foregoing, various modifications within a range not departing from the spirit of the present invention are possible. For example, in the embodiments, dimensions, impurity concentrations, etc. of regions may be variously set according to required specifications. Further, in the embodiments, while a MOSFET is described as an example, without limitation hereto, wide application to various silicon carbide semiconductor devices that conduct and block current by gate driving control based on a predetermined gate threshold voltage is possible. A silicon carbide semiconductor device under gate driving control is, for example, an insulated gate bipolar transistor (IGBT). Further, in the embodiments described, while a case in which silicon carbide is used as the wide-bandgap semiconductor material is described as an example, a wide-bandgap semiconductor material other than silicon carbide such as, for example, gallium nitride (GaN) may be used. Further, in the embodiments, while the first conductivity type is an n-type and the second conductivity type is a p-type, the present invention is similarly implemented when the first conductivity type is a p-type and the second conductivity type is an n-type.

According to the embodiments of the present invention, when the first p⁺-type region (second semiconductor region of the second conductivity type) of the bottom of the trench is formed, an element that corresponds to the p-type impurity is implanted at a predetermined ratio after etch back and removal of the oxide film. As a result, an element that is displaced by the p-type impurity may bond with the element that corresponds to the p-type impurity and may become crystallized with silicon carbide. Thus, formation of defects by the element that is displaced by the p-type impurity may be reduced. Therefore, the silicon carbide semiconductor device according to the present invention may suppress the leak current l_{DSS} during high voltage.

Further, in the embodiments of the present invention, the first p⁺-type region is formed after trench formation and therefore, widening of the width of the first p⁺-type region for alignment is unnecessary. Thus, the silicon carbide semiconductor device according to the embodiments of the present invention enables the width of the first p⁺-type region to be reduced, whereby the interval between trenches may be reduced and reductions in size may be achieved.

The semiconductor device and method of manufacturing a semiconductor device of the embodiments of the present invention achieve an effect in that increases in the leak current l_{DSS} during high voltage may be suppressed and reductions in size may be achieved.

As described, the semiconductor device and method of manufacturing a semiconductor device according to the embodiments of the present invention are useful for power semiconductor devices used in power converting equipment and in power supply devices such as those used in various machines, and are particularly suitable for silicon carbide semiconductor devices having a trench gate structure.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate of a first conductivity type;
a first semiconductor layer of the first conductivity type, provided on a front surface of the semiconductor substrate;
a second semiconductor layer of a second conductivity type, provided on a first side of the first semiconductor layer, opposite a second side of the first semiconductor layer toward the semiconductor substrate;
a first semiconductor region of the first conductivity type, selectively provided in the second semiconductor layer, the first semiconductor region having an impurity concentration that is higher than that of the semiconductor substrate;
a trench penetrating the first semiconductor region and the second semiconductor layer, and reaching the first semiconductor layer;
a gate electrode provided in the trench, via a gate insulating film;
a first electrode in contact with the first semiconductor region and the second semiconductor layer;
a second electrode provided on a rear surface of the semiconductor substrate; and
a second semiconductor region of the second conductivity type, selectively provided in the first semiconductor layer, the second semiconductor region contacting a bottom of the trench and having an impurity concentration that is higher than that of the second semiconductor layer, wherein
the second semiconductor region is implanted with an impurity and a first element at a predetermined ratio, the impurity determining a conductivity type of the second semiconductor region and displacing a second element, the first element bonding with the displaced second element.

2. The semiconductor device according to claim 1 and further comprising
a third semiconductor region of the second conductivity type, selectively provided in the first semiconductor layer, the third semiconductor region having an impurity concentration higher than that of the second semiconductor layer, wherein
an interface of the third semiconductor region and the first semiconductor layer is closer to the semiconductor substrate than is an interface of the second semiconductor region and the first semiconductor layer.

3. The semiconductor device according to claim 1, wherein
the first element is carbon, when the impurity is an impurity that enters a silicon site, and
the first element is silicon, when the impurity is an impurity that enters a carbon site.

4. The semiconductor device according to claim 1, wherein
the impurity is aluminum and the first element is carbon.

5. A method of manufacturing a semiconductor device, the method comprising:
forming a first semiconductor layer of a first conductivity type on a front surface of a semiconductor substrate of the first conductivity type;
forming a second semiconductor layer of a second conductivity type on a first side of the first semiconductor layer, opposite a second side of the first semiconductor layer toward the semiconductor substrate;
selectively forming a first semiconductor region of the first conductivity type in the second semiconductor layer, the first semiconductor region having an impurity concentration that is higher than that of the semiconductor substrate;
forming a trench that penetrates the first semiconductor region and the second semiconductor layer, and reaches the first semiconductor layer;
forming an oxide film in the trench;
removing the oxide film at a bottom of the trench;
forming a second semiconductor region of the second conductivity type in the first semiconductor layer by co-implanting in the bottom of the trench, an impurity that determines a conductivity type and a first element that bonds with a second element that is displaced by the impurity, the second semiconductor region being in contact with the bottom of the trench and having an impurity concentration that is higher than that of the second semiconductor layer;
forming a gate electrode in the trench, via a gate insulating film;
forming a first electrode in contact with the first semiconductor region and the second semiconductor layer; and
forming a second electrode on a rear surface of the semiconductor substrate.
